(19) United States
(12) Patent Application Publication
(10) Pub. No.: US 2019/0012536 A1
(43) Pub. Date: Jan. 10, 2019

(54) METHOD AND COMPUTER FOR PERMANENT MONITORING OF AN EXAMINATION ROOM

(71) Applicant: Siemens Healthcare GmbH, Erlangen (DE)

(72) Inventors: George William Ferguson, Erlangen (DE); Stephan Nufer, Erlangen (DE); Dominik Paul, Erlangen (DE)

(73) Assignee: Siemens Healthcare GmbH, Erlangen (DE)

(21) Appl. No.: 16/025,620

(22) Filed: Jul. 2, 2018

(30) Foreign Application Priority Data
Jul. 4, 2017 (EP) 17179594.1

(51) Int. Cl. G06K 9/00; G01R 33/28; G08B 3/10; G08B 5/36

(52) U.S. Cl. CPC G06K 9/00369; G01R 33/283; G08B 5/36; G06K 9/00744; G08B 3/10; G01R 33/288

(57) ABSTRACT

A monitoring method and system for monitoring a magnetic resonance apparatus having a scanner with an examination region, a video camera obtains images from an acquisition region that includes at least one of accesses to the examination room in which the scanner is situated, and a region upstream of the examination region. The images are evaluated in a processor to determine whether an alarm condition, which is different from only detecting a person, is met. When the alarm condition is met, the processor causes an alarm to be emitted that is perceptible within the examination room.

### BACKGROUND OF THE INVENTION

### Field of the Invention

The present invention concerns a monitoring method for an examination room in which a magnetic resonance system having an examination region, in particular an examination tunnel, is situated. The present invention also concerns a monitoring system and a non-transitory, computer-readable data storage medium that implements such a method.

The present invention also concerns an evaluation computer that implements such a monitoring.

The present invention also concerns an examination room, having a magnetic resonance (MR) system sutured therein, the MR system having an examination region, in particular an examination tunnel and wherein a video camera system is associated with the examination room, with which images are acquired from an acquisition region, wherein the acquisition region encompasses a region upstream of the examination region, and wherein the video camera system is connected to an evaluation computer.

### Description of the Prior Art

An examination room of the above general type is known from DE 10 2015 211 148 A1 and from the corresponding US 2016 0 367 169 A1. With this examination room, images are acquired from the region upstream of the examination region during the course of preparation of an examination. A person is localized using the acquired images. Information can be projected onto particular body parts of the person as a function of the acquired localization.

Magnetic resonance systems often have a superconducting basic field magnet, which generates a high static basic magnetic field of for example 1.5 T or 3 T. The strong magnetic field attracts ferromagnetic objects with a correspondingly strong force. The magnetic field can impair the function of a cardiac pacemaker or a different implant. It can also result in ferromagnetic objects, which are accidentally brought into the region of the force field, being attracted by the force field. As a result, the ferromagnetic object can cause damage if it strikes objects or a person.

The owner/operator of the magnetic resonance system is obliged to train operating personnel of the magnetic resonance system appropriately so as to avoid such incidents, as well as to also post appropriate warning notices at the accesses to the (closed) examination room in which the magnetic resonance system is located. Nevertheless, accidents continue to occur due to untrained personnel or patients or relatives of patients, who enter the examination room and bring magnetizable objects with them, for example an oxygen cylinder, a ventilator, a wheelchair or, in the case of cleaning personnel, cleaning equipment or a floor polisher. The appropriate warning signs are either not seen or not observed. In some cases, the danger is underestimated by persons entering the room, despite cognition of the warning signs. In rare cases, accidents of this kind occur even with personnel who have been trained appropriately, if the training occurred a long time ago.

### SUMMARY OF THE INVENTION

An object of the present invention is to provide a monitoring method and system which dangerous situations of this kind and accidents can be avoided as much as possible.

According to the invention, a monitoring method of the general type mentioned in the introduction makes use of an evaluation processor that, independently of operation of the magnetic resonance system, receives images of an acquisition region from a video camera system, wherein the acquisition region encompasses accesses to the examination room and/or a region upstream of the examination region. Whenever, in a standby mode, the evaluation processor detects a person in the received images, it checks whether an alarm condition different from just the detection of a person is met. Whenever the alarm condition is met, the evaluation processor changes into an alarm state in which, at least once, it emits at least one acoustic signal that is audible in the examination room, and/or emit an optical signal that is visible in the examination room, and otherwise maintains the standby mode. In the alarm state, the evaluation processor checks whether a termination command has been specified to it via a man-machine interface. Upon receipt of the termination command, the evaluation processor changes into an off-state in which it no longer emits the acoustic signal and/or the optical signal. In the alarm state and in the off-state, the evaluation processor checks whether it still detects the person in the images. Whenever it still detects the person in the alarm state and in the off-state, the evaluation processor maintains the current state and otherwise passes into the standby mode.

The video camera system and the evaluation processor are therefore inventively used not just during the course of operation of the magnetic resonance system (in other words, during the course of examinations and in the preliminary stage of such examinations), but operate more or less continuously. The evaluation processor firstly checks whether it detects a person at all. Detection of a person as such (per se) still does not trigger an alarm, however. Instead, an alarm is triggered only if an alarm condition is also met. The alarm condition is met if, using additional criteria aside from the “mere” detection of a person, it is detected that a dangerous situation could exist. In this case an acoustic signal and/or an optical signal is emitted as an output, in other words an appropriate warning.

In some cases the warning will be a false alarm. This is not critical, however, since in this case the false alarm can be ended by specifying the termination command.

The alarm condition can be configured in various ways.

For example, the alarm condition may be met only if, in addition to the person, the evaluation processor detects in the received images an object on the detected person that is different from the person and his or her clothing. Detection of the object is a necessary condition, but not imperatively an adequate one for meeting the alarm condition. It is possible for the detection of the object to already be adequate for changing to the alarm state, but it is not obligatory. For example, it is possible that the alarm condition is only met if the detected object adequately matches at least one predetermined object type. The object types can be specified as required to minimize the aforementioned risks. For example, the object types can be a cylinder (for example an oxygen cylinder), a chair (in particular a wheelchair), a watch and/or glasses. Other object types, such as a ventilator, a bed or a patient bed, a mop, a broom or motor-driven cleaning equipment are also conceivable.

Alternatively or additionally, the alarm condition may be met only if the detected person is in a predetermined section of the acquisition region. For example, the region of the magnetic resonance system which should be regarded as a “danger zone” can be determined in advance. In this case, a safety zone is also defined around the danger zone and this safety zone is also defined as a corresponding section of the acquisition region. In this case, the alarm condition is therefore only met if the detected person moves into the safety zone *thereby allowing the alarm to be emitted before the person is in the danger zone).

Alternatively or additionally, the alarm condition is met only if the detected person is a person different from at least one predetermined person. In this case, triggering of the acoustic signal can be limited to cases in which a person is detected who is not “known” to the evaluation processor as being authorized.

The evaluation processor can perform a 2D evaluation of the images acquired by the video camera system, but the evaluation processor preferably performs a 3D evaluation of the images acquired by the video camera system. Such a 3D evaluation also provides an item of depth information. As a result it is often easier to evaluate the region in which a person is situated and/or whether and possibly which, further object is detected on the person.

The alarm condition can be statically specified to the evaluation processor. In a preferred embodiment, the evaluation processor is designed as a self-learning system. In this case it is possible for the evaluation processor, when the termination command has been specified to it in the alarm state, to modify the alarm condition such that a situation, for which the alarm condition was previously regarded as having been met, to be removed from the alarm condition definition, or at least a lower weighting is associated with that situation.

The present invention also encompasses a non-transitory, computer-readable data storage medium encoded with programming instructions that, when loaded into a computer of a monitoring system, and possibly distributively loaded into other components of the monitoring system, cause the computer to operate the monitoring system in order to implement any or all embodiments of the method according to the invention as, described above.

The object is also achieved by a monitoring system of the type mentioned in the introduction wherein the acquisition region, alternatively or additionally to the region upstream of the examination region, encompasses accesses to the examination room, and the monitoring system has an evaluation processor according to the invention, as described above.

### BRIEF DESCRIPTION OF THE DRAWINGS

FIG. 1 shows an examination room with monitoring system according to the invention, with a magnetic resonance apparatus located therein, from the side.

FIG. 2 shows the examination room of FIG. 1 from above.

FIGS. 3 to 7 show flowcharts for explaining various embodiments of the invention.

### DESCRIPTION OF THE PREFERRED EMBODIMENTS

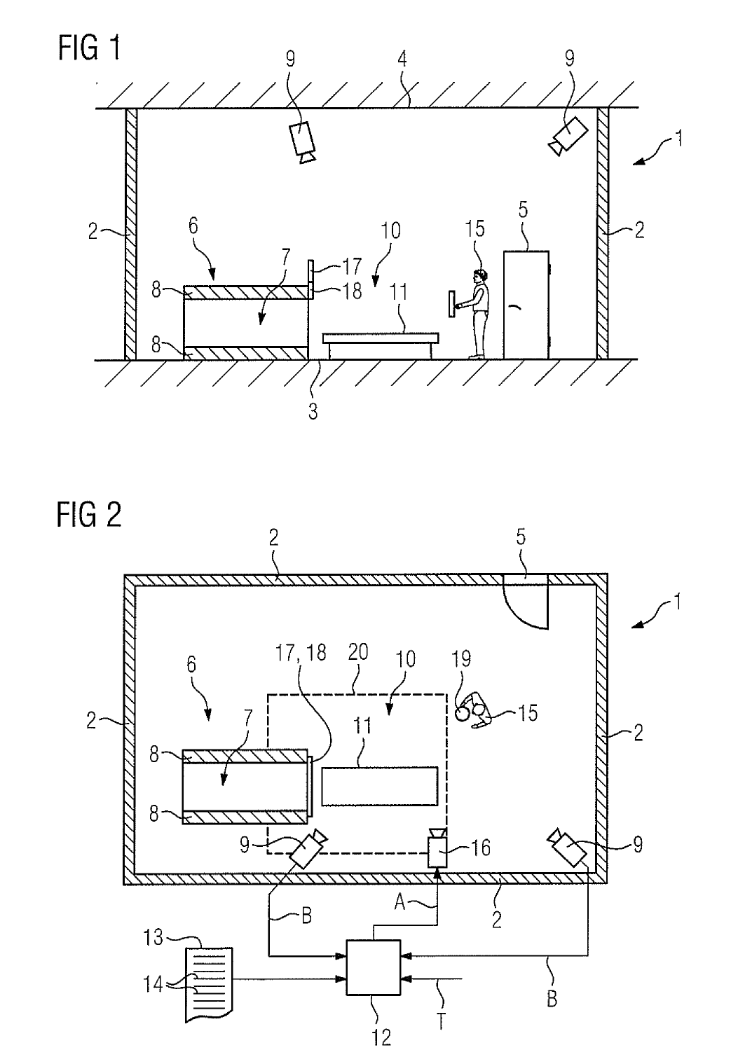

According to FIGS. 1 and 2, an examination room 1 has walls 2, a floor 3 and a ceiling 4. The walls 2 can be transparent or non-transparent as required, for example partially glazed. At least one wall 2 has an access 5 to the examination room 1, in other words, a door opening.

A magnetic resonance scanner 6 of a magnetic resonance system is situated in the examination room 1. The magnetic resonance scanner 6 has an examination region 7, for example an examination tunnel. The examination region 7 of the magnetic resonance scanner 6 is the region in which a temporally static, locally essentially homogeneous magnetic field (in practice usually called a B0 field) is generated by a basic field magnet 8 of the magnetic resonance scanner 6. The B0 field has a high magnetic field strength, for example 1.5 T or more.

A video camera system 9 is associated with the examination room 1. The video camera system 9 can be arranged inside the examination room 1. Images B are acquired from an acquisition region by means of the video camera system 9. The acquisition region comprises the accesses 5 to the examination room 1 and/or a region 10 upstream of the examination region 7, for example the region in which an examination table 11 is located before introduction of the examination table 11 into the examination region 7.

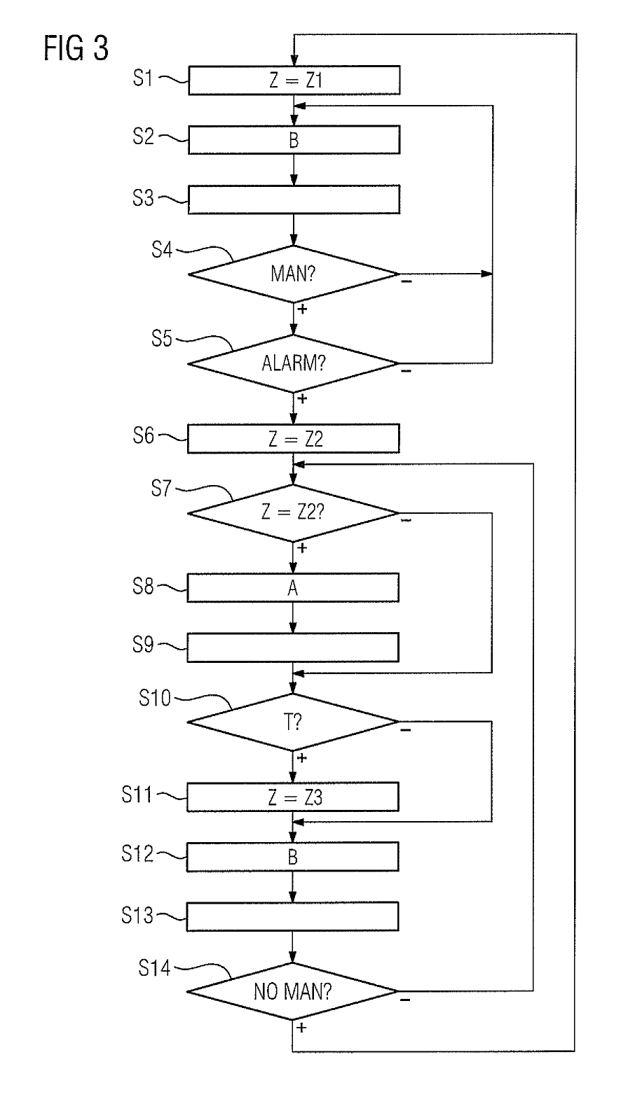

According to FIG. 2, the video camera system 9 is connected to an evaluation processor 12. The evaluation processor 12 is programmed with a computer program 13. The computer program 13 includes machine code 14, which can be executed by the evaluation processor 12. Execution of the machine code 14 by the evaluation processor 12 causes the evaluation processor 12 to carry out a monitoring method during operation, which will be illustrated in more detail below in connection with FIG. 3.

First, a state Z of the evaluation processor 12 according to FIG. 3 is set to a standby mode Z1 in a step S1. In the standby mode Z1 the evaluation processor 12 receives a group of images B from the video camera system 9 in a step S2. The group of images B are those images B, which are acquired by the video camera system 9 at a particular instant. It is possible that the group is just a single image B. Alternatively, the group can comprise a number of images B.

In a step S3 the evaluation processor 12 performs an evaluation of the received group of images B. It is possible that the evaluation processor 12 performs a 2D evaluation of the group of images B. The evaluation processor 12 preferably performs a 3D evaluation of the group of images, however. For example, an item of depth information can be determined from the respective image B for at least one of the acquired images B on the basis of a corresponding projection of a known pattern in the acquisition region. Alternatively, it is possible, by correlation of a number of images B, to determine a corresponding three-dimensional item of information. The relevant modes of procedure are generally known to persons skilled in the art.

In a step S4 the evaluation processor 12 checks whether it detects a person 15 during the course of the evaluation. The detection of step S4 should not be understood as meaning identification of the actual person 15. It is therefore not a matter of whether a particular person 15 is detected (“that is Mr. Müller”), but whether a person 15 is detected at all (“there is someone here”). If the evaluation processor 12 detects a person 15, the evaluation processor 12 moves to step S5. Otherwise it returns to step S2.

In step S5 the evaluation processor 12 checks whether an alarm condition is met. The alarm condition is a condition different from detection of a person 15 per se. Detection of a person 15 per se, therefore, does not always or necessarily trigger an alarm, but an alarm is triggered only if in addition the alarm condition is met. Possible embodiments of the alarm condition will be illustrated in more detail below in connection with the further figures. If the alarm condition is met, the evaluation processor 12 moves to a step S6. Otherwise, it returns to step S2.

In step S6, the state Z of the evaluation processor 12 is set to an alarm state Z2. The evaluation processor 12 therefore moves into the alarm state Z2. In a subsequent step S7 the evaluation processor 12 checks whether it is in the alarm state Z2. If this is the case, the evaluation processor 12 carries out step S8. Otherwise, step S8 is skipped. In step S8 the evaluation processor 12 emits an alarm signal A. The alarm signal A usually is an acoustic signal. Examples of suitable acoustic signals are a conventional alarm sound (sound of a horn, siren sound and the like) or the emitting of an appropriate spoken message, such as “Caution! There is a very strong magnetic field here. Go back immediately”. The acoustic signals can be emitted via a loudspeaker 16 (see FIGS. 1 and 2). The acoustic device, via which the acoustic signal is output, —for example the loudspeaker 16—is situated such that the acoustic signal can be heard in the examination room 1.

Alternatively or additionally, the evaluation processor 12 emits an optical signal in step S8. For example, the evaluation processor 12 can switch on a yellow or red flashing light or, via a display device 17, (see FIGS. 1 and 2) show a text message, corresponding to the spoken message, to the person 15. The optical device, via which the evaluation processor 12 emits the optical signal, is situated such that the optical signal is visible in the examination room 1. For example, the display device 17 can be located in the region immediately upstream of the examination region 7.

Step S9 can follow step S8 in which the evaluation processor 12 takes further measures, for example transmits appropriate messages to devices arranged remotely, so that emergency measures can be initiated there.

In step S10 the evaluation processor 12 checks whether a termination command T has been specified to it via a human-machine interface 18. If the termination command T is specified, the evaluation processor 12 moves to a step S11. In step S11 the state Z of the evaluation processor 12 is set into an off-state Z3. Otherwise, the evaluation processor 12 skips step S11.

The evaluation processor 12 then receives a group of images B from the video camera system 9 in a step S12 and evaluates the received group of images B in a step S13. Steps S12 and S13 correspond in terms of content to steps S2 and S3.

In a step S14 the evaluation processor 12 checks whether it does not detect a person during the course of the evaluation, in other words, no longer detects the person 15. If the evaluation processor 12 continues to detect the person 15, the evaluation processor 12 returns to step S7. Otherwise, it returns to step S1.

Due to the checking in step S7, the evaluation processor 12 therefore no longer emits the acoustic signal and/or the optical signal if it is in the off-state Z3.

It is possible that step S7 as such is not present. In this case the evaluation processor 12 passes from step S14 either to step S9 (if present) or to step S10. In this case the alarm signal A is only emitted once during the transition from standby mode Z1 into the alarm state Z2.

The approach of FIG. 3 is carried out independently of operation of the magnetic resonance scanner 6, preferably “around the clock” (24/7). It is therefore in particular also carried out at times at which no examinations at all are to be performed with the magnetic resonance scanner 6.

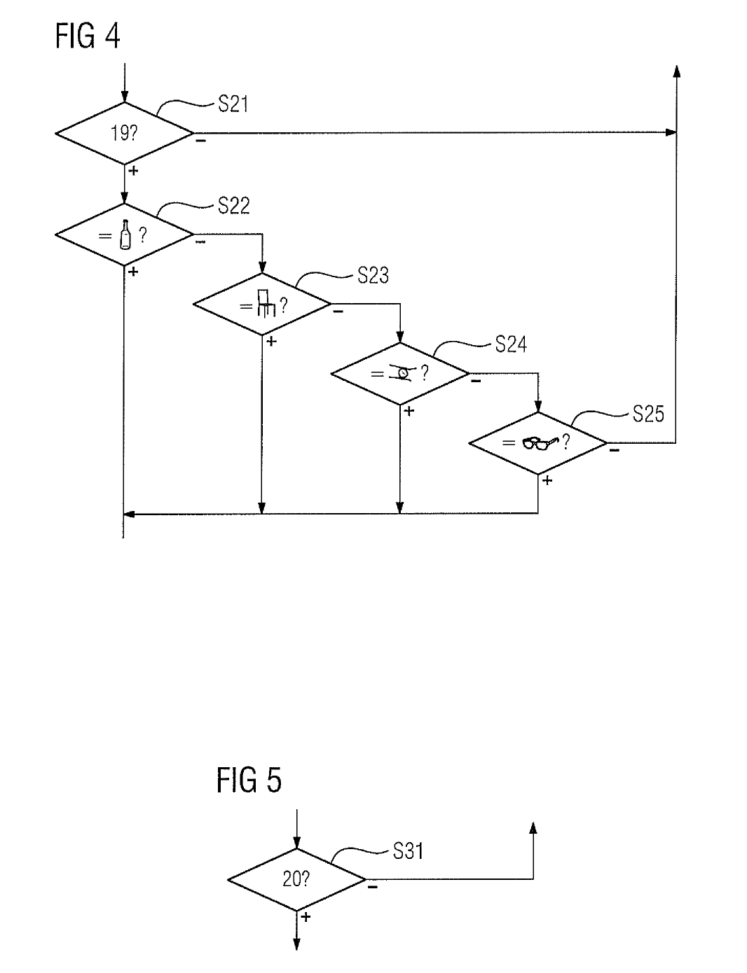

The alarm condition can, as already mentioned, be configured in different ways. Some of the possible embodiments will be illustrated in more detail below in connection with FIGS. 4 to 6. FIGS. 4 to 6 therefore show possible embodiments of step S5 of FIG. 3.

According to FIG. 4, in one possible embodiment the evaluation processor 12 checks in step S21 whether it detects a further object 19 on the person 15 in addition to the detected person 15 (wherein the clothing of the person 15 is regarded as a component of the person 15). It is possible that the check of step S21 is the only check. In this case the detection of the further object 19 as such decides whether the alarm condition is met or not. Detection of the further object 19 is in this case therefore not just a necessary condition, but also an adequate one for regarding the alarm condition as being met. The alarm condition corresponding to the diagram in FIG. 4 is preferably only met, however if the detected object 19 sufficiently matches at least one predetermined object type. For example, according to the flowchart in FIG. 4 it can be successively checked whether the detected object 19 has sufficient similarity to a bottle, a chair, a watch and/or glasses. The corresponding checks are shown in FIG. 4 in steps S22 to S25. Of course, not all illustrated checks have to be performed. Furthermore, as required, other or additional checks can also be made. Checking methods, by which corresponding object types can be detected, are generally known to those skilled in the art, and do not need to be described in more detail herein.

Furthermore, according to the flowchart in FIG. 5, it is possible for the evaluation processor 12 to check in step S31 whether the detected person 15 is in a predetermined section 20 of the acquisition region. For example, it is possible that the alarm condition is still not met provided the detected person 15 is sufficiently far removed from the magnetic resonance scanner 6 and in particular the examination region 7. If the detected person 15 moves into the predetermined section 20 by contrast, the alarm condition can be assumed to be met—with or without checking further conditions—and therefore the alarm can be triggered. The check according to FIG. 5 can, as required, be combined with the check according to FIG. 4. For example, it is possible to carry out the two checks independently of each other, so that the alarm condition is already met, and one of the two checks is positive. Alternatively, it is possible to combine the two checks within the meaning of an AND operation, so that the alarm condition is only met if, firstly, the additional object 19 (optionally including object type) was detected and, furthermore, the person 15 is in the predetermined section 20. For example, the approach of FIG. 5 can be carried out for this purpose as a preliminary check before the check according to FIG. 4.

It is also possible to perform the check of FIG. 5 in several stages, for example, in other words, to define a number of nested sections, and to output a more intensive warning, the further the person 15 progresses.

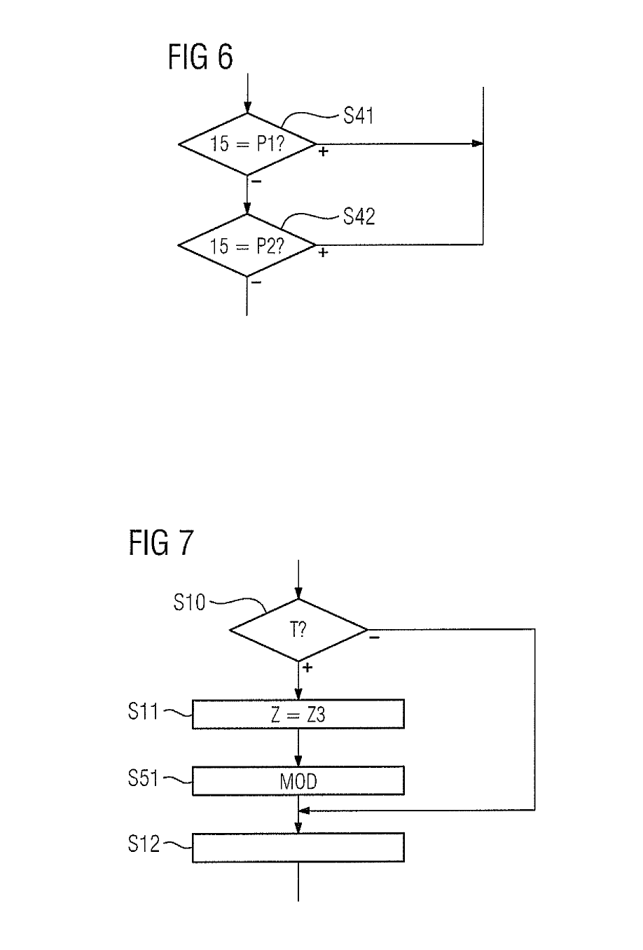

Furthermore, according to the flowchart in FIG. 6 it is possible for the evaluation processor 12 to check in steps S41 and S42 whether it can identify the detected person 15, whether, in other words, it can detect for example in step S41 that the detected person 15 is a first, known person P1 (“that is Mr. Müller”), or in step S42 can detect that the detected person 15 is a second, known person P2 (“that is Mrs. Braun”). This approach can of course also be expanded to more than two people. In this case the alarm condition can be met if the evaluation processor 12 cannot identify the detected person 15. In this case the evaluation processor 12 could detect during the course of the evaluation of step S3 that a person 15 is present, but not who the person 15 is.

The identification of the person can be configured as required. In particular, appropriate methods of facial recognition are generally known to persons skilled in the art. Alternatively or additionally, the stature of the person 15 can also be evaluated.

In the case of simultaneous detection of a number of individuals 15, the embodiment of FIG. 6 can be configured such that the alarm condition is regarded as met, and the evaluation processor 12 cannot identify one of the individuals 15. In the case of detection of a plurality of individuals 15, the alarm condition is preferably only regarded as met, however, if the evaluation processor 12 cannot identify any of the detected individuals 15. The approach of FIG. 6 can also be combined, as required—be it as an alternative, be it as an additional condition—with the approach of FIG. 4, FIG. 5 or FIGS. 4 and 5.

As a rule, the alarm condition is static from the perspective of the evaluation processor 12. It is therefore specified to the processor 12 from outside and is not modified by the evaluation processor 12. It is, however, possible for the evaluation processor 12 to be self-learning insofar as it can independently learn “non-critical” situations. This will be illustrated in more detail below in connection with FIG. 7.

FIG. 7 starts from FIG. 3. Reference will therefore be made to the statements above relating to FIG. 3 (and also the embodiments according to FIGS. 4 to 6. In addition there is a step S51, however. Step S51 is subordinate to step S11. It is therefore carried out if the termination command T is specified to the evaluation processor 12 in the alarm state Z2. In step S51 the evaluation processor 12 modifies the alarm condition. The modification is such that the situation, detected during the course of evaluation of the group of images B, owing to which the alarm condition was regarded as having been met, is removed from the alarm condition. At any rate a lower weighting is associated with this situation in step S51. In the first case, the situation is immediately removed from the alarm condition. In the second case, the situation is weighted increasingly less, so, as a result, it is removed from the alarm condition after a number of iterations.

The present invention has many advantages. In particular, it is possible to almost completely prevent accidents, which can be attributed to accidental disregard of the safety regulations. The operational safety can be significantly increased.

Although modifications and changes may be suggested by those skilled in the art, it is the intention of the Applicant to embody within the patent warranted hereon all changes and modifications as reasonably and properly come within the scope of the Applicant's contribution to the art.

1. A monitoring method for a magnetic resonance apparatus situated in an examination room, said magnetic resonance apparatus comprising a magnetic resonance scanner having an examination region therein that has an opening in said magnetic resonance scanner, said monitoring method comprising:
independently of operation of the magnetic resonance scanner, operating a video camera to obtain images from an acquisition region of the video camera, said acquisition region encompassing at least one of accesses to the examination room, and a region in front of said opening of the examination region;
providing said images to a computer and, in a standby mode of said computer, detecting a presence of a person in the received images and thereupon detecting whether an alarm condition, that is different from only detection of the presence of a person, is met;
when said alarm condition is met, said computer changing into an alarm state in which said computer emits an alarm selected from the group consisting of at least one acoustic signal that is audible in the examination room, and an optical signal that is visible in the examination room, and when said alarm condition is not met, said computer maintaining said standby mode;
when said computer is in said alarm state, checking, in said computer, whether a termination scan has been received by the computer via a man-machine interface of the computer;
if said termination command is received by said computer, said computer changing into an off-state in which said computer no longer emits said alarm;
in said alarm state and in said off-state of said computer, checking, in said computer, whether said person is still detected in said images; and
when said computer still detects said person in said images in said alarm state and in said off-state, maintaining said computer in said alarm state or said off-state, and otherwise changing said computer into said standby mode.

2. A monitoring method as claimed in claim 1 comprising, in said computer, determining said alarm condition is met when, in addition to detecting a person in said images, said computer detects an object in said images that is different from the person in the images and clothing of the person in the images.

3. A monitoring method as claimed in claim 2 wherein said computer determines said alarm condition to be met only if said object matches a predetermined object type.

4. A monitoring method as claimed in claim 3 comprising selecting said object type from the group consisting of a bottle, a chair, a watch, and eyeglasses.

5. A monitoring method as claimed in claim 1 wherein said computer determines said alarm condition to be met only when the person detected in said images is situated in the a predetermined section of said acquisition region.

6. A monitoring method as claimed in claim 1 wherein said computer determines said alarm condition to be met only if the person detected in said images is different from at least one predetermined person.

7. A monitoring method as claimed in claim 1 wherein said computer performs a 3D evaluation of said images in order to determine whether said alarm condition is met.

8. A monitoring method as claimed in claim 1 comprising, after receiving said termination command, executing, in said computer, an algorithm to modify said alarm condition by identifying the detection made by the computer that resulted in the termination command and either removing said detection from said alarm condition or giving said detection a low weighting for determining when said alarm condition is met in the future.

9. A non-transitory, computer-readable data storage medium encoded with programming instructions, said storage medium being loaded into a computer of a monitoring system that also comprises a video camera, and that monitors a magnetic resonance apparatus situated in an examination room, wherein the magnetic resonance apparatus comprises a magnetic resonance scanner having an examination region with an opening in said magnetic resonance scanner, said storage medium being encoded with programming instructions that cause said computer to:
independently of operation of the magnetic resonance scanner, operate a video camera to obtain images from an acquisition region of the video camera, said acquisition region encompassing at least one of accesses to the examination room, and a region in front of said opening of the examination region;
receive said images in said computer and, in a standby mode of said computer, detect a presence of a person in the received images and thereupon detect whether an alarm condition, that is different from only detection of the presence of a person, is met;
when said alarm condition is met, change into an alarm state in which said computer emits an alarm selected from the group consisting of at least one acoustic signal that is audible in the examination room, and an optical signal that is visible in the examination room, and when said alarm condition is not met, said computer maintaining said standby mode;
when said computer is in said alarm state, check whether a termination scan has been received by the computer via a man-machine interface of the computer;
if said termination command is received by said computer, change into an off-state in which said computer no longer emits said alarm;
in said alarm state and in said off-state of said computer, check whether said person is still detected in said images; and
when said computer still detects said person in said images in said alarm state and in said off-state, maintain said computer in said alarm state or said off-state, and otherwise change said computer into said standby mode.

10. A monitoring computer for a magnetic resonance apparatus situated in an examination room, said magnetic resonance apparatus comprising a magnetic resonance scanner having an examination region therein that has an opening in said magnetic resonance scanner, said monitoring computer comprising:
a man-machine interface;
an output at which signals are emitted to a video camera in order to operate the video camera independently of operation of the magnetic resonance scanner, to obtain images from an acquisition region of the video camera, said acquisition region encompassing at least one of accesses to the examination room, and a region in front of said opening of the examination region;
an input to which said images are provided to said computer;
a processor configured, in a standby mode of said computer, to detect a presence of a person in the received images and thereupon detecting whether an alarm condition, that is different from only detection of the presence of a person, is met;
when said alarm condition is met, said processor being configured to change into an alarm state in which said computer emits an alarm selected from the group consisting of at least one acoustic signal that is audible in the examination room, and an optical signal that is visible in the examination room, and when said alarm condition is not met, said processor maintaining said standby mode;
when said processor is in said alarm state, said processor being configured to check whether a termination scan has been received by the processor via said man-machine interface;
if said termination command is received by said processor, said processor being configured to change into an off-state in which said processor no longer emits said alarm;
in said alarm state and in said off-state of said processor, said processor being configured to check whether said person is still detected in said images; and
when said processor still detects said person in said images in said alarm state and in said off-state, said processor being configured to maintain said processor in said alarm state or said off-state, and otherwise change said processor into said standby mode.

11. A monitoring system for a magnetic resonance apparatus situated in an examination room, said magnetic resonance apparatus comprising a magnetic resonance scanner having an examination region wherein that has an opening in said magnetic resonance scanner, said monitoring system comprising:
a video camera;
a computer configured to operate said video camera independently of operation of the magnetic resonance scanner, to obtain images from an acquisition region of the video camera, said acquisition region encompassing at least one of accesses to the examination room, and a region in front of said opening of the examination region;
said computer, in a standby mode of said computer, being configured to detect a presence of a person in the images and to thereupon detect whether an alarm condition, that is different from only detection of the presence of a person, is met;
when said alarm condition is met, said computer being configured to change into an alarm state in which said computer emits an alarm selected from the group consisting of at least one acoustic signal that is audible in the examination room, and an optical signal that is visible in the examination room, and when said alarm condition is not met, said computer being configured to maintain said standby mode;
when said computer is in said alarm state, said computer being configured to check whether a termination scan has been received by the computer via a man-machine interface of the computer;
if said termination command is received by said computer, said computer being configured to change into an off-state in which said computer no longer emits said alarm;
in said alarm state and in said off-state of said computer, said computer being configured to check whether said person is still detected in said images; and
when said computer still detects said person in said images in said alarm state and in said off-state, said computer being configured to maintain said computer in said alarm state or said off-state, and otherwise to change into said standby mode.
